(19) United States
(12) Patent Application Publication
(10) Pub. No.: US 2016/0172039 A1
(43) Pub. Date: Jun. 16, 2016

(54) SEMICONDUCTOR MEMORY DEVICE AND METHOD OF OPERATING THE SAME

(71) Applicant: SK hynix Inc., Icheon (KR)

(72) Inventor: Byoung In JOO, Icheon (KR)

(21) Appl. No.: 14/702,543

(22) Filed: May 1, 2015

(30) Foreign Application Priority Data
Dec. 15, 2014 (KR) 10-2014-0180711

(51) Int. Cl. G11C 16/10; G11C 16/08; G11C 16/26

(52) U.S. Cl. CPC G11C 16/10; G11C 16/26; G11C 16/08

(57) ABSTRACT

A semiconductor memory device and a method of operating the same are provided. The device includes a memory cell array including a plurality of memory cells is arranged in a plurality of columns, a peripheral circuit configured to program selected memory cells of the memory cells when a program operation is performed, and a control logic configured to control the peripheral circuit during the program operation. The control logic controls the peripheral circuit so that a fail bit masking operation and a most significant bit (MSB) data program operation are performed concurrently during the program operation.

### CROSS-REFERENCE TO RELATED APPLICATION

The present application claims priority to Korean Patent Application Number 10-2014-0180711, filed on Dec. 15, 2014, the entire disclosure of which is incorporated herein in its entirety by reference.

### BACKGROUND

1. Field of Invention

Embodiments of the present disclosure relates to an electronic device, and more particularly, to a semiconductor memory device and a method of operating the same.

2. Description of Related Art

Semiconductor devices, specifically semiconductor memory devices, are classified into volatile memory devices and nonvolatile memory devices.

Nonvolatile memory devices have relatively slow read and write speeds. However, the nonvolatile memory devices retain stored data even when not powered. Therefore, the nonvolatile memory devices are used to store data regardless of whether power is supplied thereto or not. The nonvolatile memory devices include a read only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memories include a NOR type flash memory and a NAND type flash memory.

A flash memory has an advantage of a RAM that data programming, erasing operations are not required and an advantage of a ROM that stored data is retained even when not powered. Thus, the flash memory has been widely used as a storage medium for portable electronic devices such as a digital camera, a personal digital assistant (PDA), an MP3 player, and so on.

### SUMMARY

Embodiments of the present disclosure are directed to a semiconductor memory device having an operating time that is reduced when a program operation is performed on the semiconductor memory device, and a method of operating the same.

One aspect of the present disclosure includes a semiconductor memory device including a memory cell array including a plurality of memory cells, a peripheral circuit which programs a memory cell from the memory cells when a program operation is performed, and a control logic which controls the peripheral circuit during the program operation, and the control logic controls the peripheral circuit so that a fail bit masking operation and a most significant bit (MSB) data program operation are performed concurrently during the program operation.

Another aspect of the present disclosure includes a method of operating a semiconductor memory device including performing a least significant bit (LSB) data program operation on selected memory cells of a plurality of memory cells, performing a fail bit masking operation on the selected memory cell in which the LSB data program operation is performed, and performing an MSB data program operation while the fail bit masking operation is performed.

### BRIEF DESCRIPTION OF THE DRAWINGS

The above and other features and advantages of the present disclosure will be apparent to those of ordinary skill in the art in detailed illustrative embodiments thereof described with reference to the attached drawings, in which:

FIG. 1 illustrates a block diagram of a semiconductor memory device according to an embodiment of the present disclosure;

FIG. 2 illustrates a detailed block diagram of a control logic according to an embodiment of the present disclosure;

FIG. 3 illustrates a flowchart of a method of operating a semiconductor memory device according to an embodiment of the present disclosure;

FIG. 4 illustrates waveforms of signals used in a method of operating a semiconductor memory device according to an embodiment of the present disclosure;

FIG. 5 illustrates a block diagram of a memory system including the semiconductor memory device of FIG. 1;

FIG. 6 illustrates a block diagram of an application example of the memory system of FIG. 5; and

FIG. 7 illustrates a block diagram of a computing system including the memory system described with reference to FIG. 6.

### DETAILED DESCRIPTION

Various embodiments of the present disclosure will be described more fully with reference to the accompanying drawings. These inventive concepts may, however, be embodied in different forms and should not be construed as limited to the embodiments set forth herein. Rather, these embodiments are provided so that the present disclosure is thorough and complete and fully conveys the inventive concept to those skilled in the art.

Throughout this specification, when an element is referred to as being “connected” to another element, it includes that the element can be “directly connected” to the other element or “indirectly connected” to the other element with other intervening element(s). Throughout this specification, when a certain part “includes” a certain component, it includes that another component may be further included instead of excluding any other components unless otherwise defined.

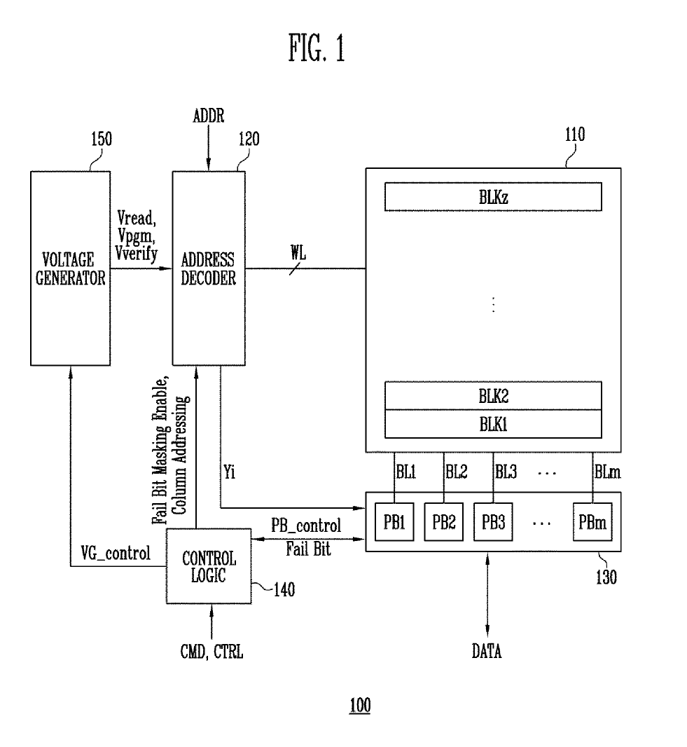

FIG. 1 illustrates a block diagram of a semiconductor memory device according to an embodiment of the present disclosure.

Referring to FIG. 1, the semiconductor memory device 100 includes a memory cell array 110, an address decoder 120, a read/write circuit 130, a control logic 140, and a voltage generator 150.

The memory cell array 110 includes a plurality of memory blocks BLK1 to BLKz, z being a positive integer. The plurality of memory blocks BLK1 to BLKz is connected to the address decoder 120 through word lines WL. The plurality of memory blocks BLK1 to BLKz is connected to the read/write circuit 130 through bit lines BL1 to BLm, m being a positive integer. Each of the plurality of memory blocks BLK1 to BLKz includes a plurality of memory cells.

In an embodiment, the plurality of memory cells is non-volatile memory cells. In a plurality of memory cells included in a memory block BLK, a group of memory cells connected to the same word line is referred to as a page. Therefore, each of the plurality of memory blocks BLK1 to BLKz in the memory cell array 110 includes a plurality of pages.

Further, each of the plurality of memory blocks BLK1 to BLKz in the memory cell array 110 includes a plurality of cell strings. A group of memory cells serially connected to the same bit line is referred to as a string.

The address decoder 120, the read/write circuit 130, and the voltage generator 150 operate as peripheral circuits that drive the memory cell array 110.

The address decoder 120 is connected to the memory cell array 110 through the word lines WL. The address decoder 120 is configured to operate in response to control of the control logic 140. The address decoder 120 receives an address ADDR through an input/output buffer (not shown) in the semiconductor memory device 100.

The address decoder 120 applies a program voltage Vpgm generated by the voltage generator 150 to a selected word line of a selected memory block when a program operation is performed. The address decoder 120 applies a program verify voltage Vverify generated by the voltage generator 150 to the selected word line of the selected memory block when a program verify operation is performed. Further, the address decoder 120 applies a read voltage Vread generated by the voltage generator 150 to the selected word line of the selected memory block when a read operation for reading least significant bit (LSB) data programmed in a memory cell is performed before an operation for programming most significant bit (MSB), i.e., an MSB data program operation, is performed during the program operation.

Further, when a fail bit masking operation, which is performed after an LSB data program operation is competed, is performed during the program operation, the address decoder 120 receives, from the control logic 140, a fail bit masking enable signal Fail Bit Masking Enable and a column address Column Addressing corresponding to a column of the memory cell array 110 in which a fail bit is generated. In response to the fail bit masking enable signal Fail Bit Masking Enable and the column address Column Addressing, the address decoder 120 deactivates a page buffer corresponding to the column address Column Addressing or sets the page buffer in a program inhibition mode.

The program operation is performed on the semiconductor memory device 100 in units of pages. The address ADDR includes a block address, a row address, and a column address. The address decoder 120 selects one memory block and one word line according to the block address and the row address. The column address is decoded by the address decoder 120, and a decoded column address is provided to the read/write circuit 130.

The read/write circuit 130 includes a plurality of page buffers PB1 to PBm. The plurality of page buffers PB1 to PBm is connected to the memory cell array 110 through the bit lines BL1 to BLm, respectively. When a program operation is performed, each of the plurality of page buffers PB1 to PBm temporarily stores LSB data or MSB data and then adjusts a potential level of a corresponding bit line according to the stored data. Further, when a verify operation is performed, each of the plurality of page buffers PB1 to PBm senses the potential level of the corresponding bit line.

Further, the read/write circuit 130 detects a fail bit Fail Bit with respect to an LSB data program operation using a column scanning method and transmits the fail bit Fail Bit to the control logic 140 after the LSB data program operation is completed.

The read/write circuit 130 operates in response to control of the control logic 140. The read/write circuit 130 performs a program operation, a verify operation, a fail bit check operation, and the like in response to a page buffer control signal PB_control output from the control logic 140. The fail bit check operation may be performed using a column scanning method to generate the fail bit Fail Bit.

In an embodiment, the read/write circuit 130 may include page buffers (or page registers), a column select circuit, etc.

The control logic 140 is connected to the address decoder 120, the read/write circuit 130, and the voltage generator 150. The control logic 140 receives a command CMD and a control signal CTRL through the input/output buffer (not shown) in the semiconductor memory device 100. The control logic 140 is configured to control overall operations of the semiconductor memory device 100 in response to the command CMD and the control signal CTRL. Further, the control logic 140 controls the address decoder 120, the read/write circuit 130, and the voltage generator 150 so that, in the program operation, some processes of an MSB data program operation are performed while a fail bit masking operation is performed after an LSB data program operation on the memory cell array 110 is completed.

The control logic 140 receives the fail bit Fail Bit from the read/write circuit 130 and outputs the column address Column Addressing corresponding to the fail bit Fail Bit to the address decoder 120. Further, the control logic 140 outputs the fail bit masking enable signal Fail Bit Masking Enable when the fail bit masking operation is performed.

The voltage generator 150 generates the program voltage Vpgm when a program voltage apply operation is performed, and generates the verify voltage Vverify when a verify operation is performed during the program operation, in response to a voltage generator control signal VG_control output from the control logic 140. Further, before the MSB data program operation is performed after the LSB data program operation is completed, the voltage generator 150 generates the read voltage Vread for reading the LSB data stored in the memory cell.

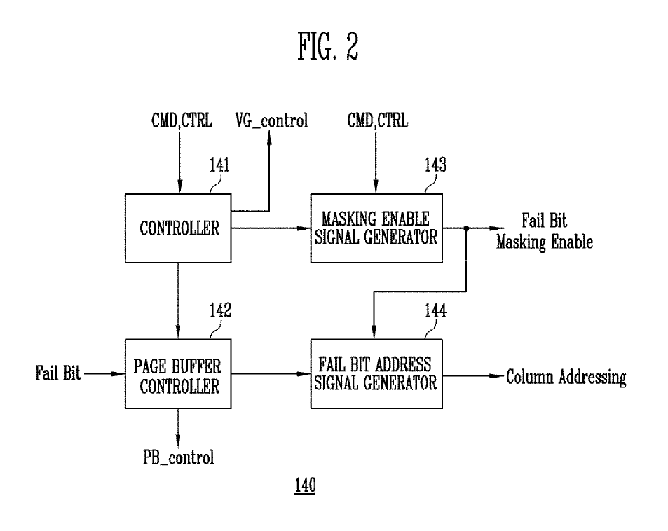

FIG. 2 illustrates a detailed block diagram of the control logic shown in FIG. 1 according to an embodiment of the present disclosure.

Referring to FIG. 2, the control logic 140 includes a controller 141, a page buffer controller 142, a masking enable signal generator 143, and a fail bit address signal generator 144.

The controller 141 generates the voltage generator control signal VG_control in response to the command CMD and the control signal CTRL, which are input through the input/output buffer (not shown), and controls the page buffer controller 142 and the masking enable signal generator 143 in order to control the address decoder 120 and the read/write circuit 130 when each of overall operations is performed in response to the command CMD and the control signal CTRL.

The page buffer controller 142 outputs the page buffer control signal PB_control for controlling the read/write circuit 130 when a program operation or a verify operation is performed. Further, when a fail bit check operation is performed using a column scanning method, the page buffer controller 142 may receive a fail bit Fail Bit from the read/write circuit 130, and output information about the fail bit Fail Bit to the fail bit address signal generator 144.

The masking enable signal generator 143 generates and outputs a fail bit masking enable signal Fail Bit Masking Enable according to control of the controller 141 when an LSB data program operation is completed during the program operation.

The fail bit address signal generator 144 is activated in response to the fail bit masking enable signal Fail Bit Masking Enable and outputs the column address Column Addressing corresponding to the fail bit Fail Bit based on the fail bit information received from the page buffer controller 142.

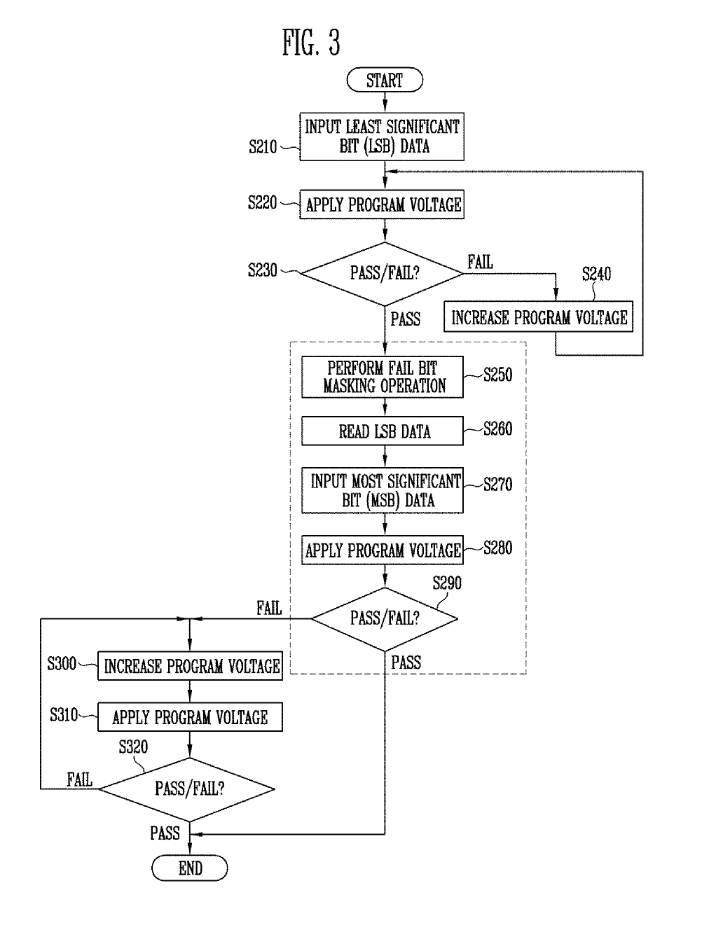

FIG. 3 illustrates a flowchart of a method of operating the semiconductor memory device shown in FIGS. 1 and 2 according to an embodiment of the present disclosure.

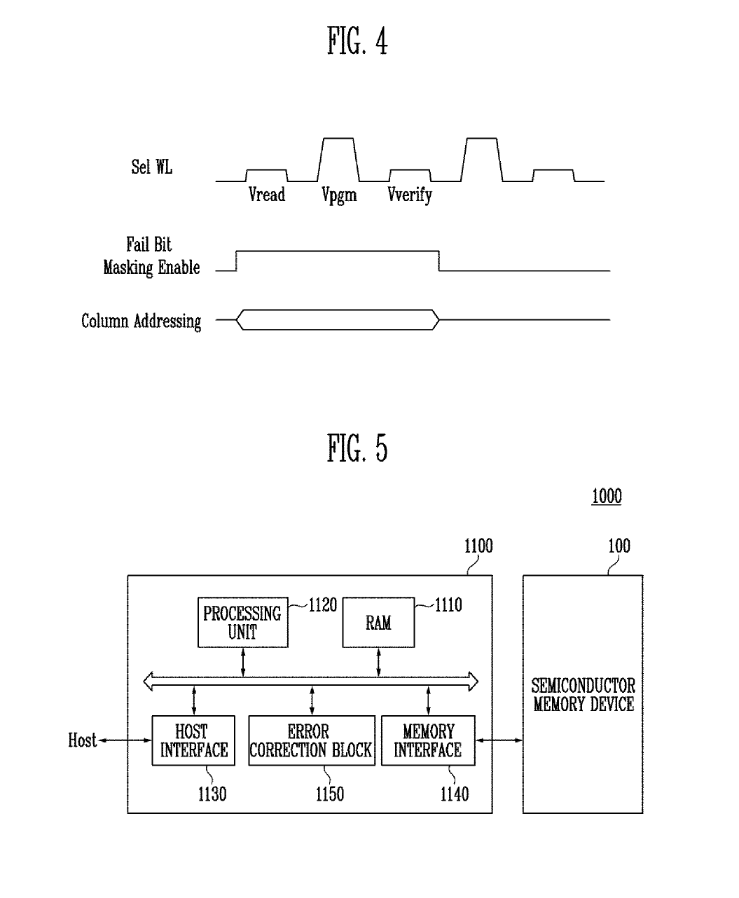

FIG. 4 illustrates waveforms of signals used in the method of operating the semiconductor memory device shown in FIG. 3 according to an embodiment of the present disclosure.

The method of operating the semiconductor memory device according to the embodiment of the present disclosure will be described below with reference to FIGS. 1 to 4.

1) Input LSB Data (S210)

When a program command CMD is input from the outside of the semiconductor memory device, the control logic 140 outputs control signals for performing a program operation. The read/write circuit 130 temporarily stores LSB data of program data in response to a page buffer control signal PB_control and adjusts potential levels of the bit lines BL1 to BLm according to the temporarily stored LSB data.

2) Apply Program Voltage (S220)

When a program voltage apply operation is performed, the address decoder 120 selects one memory block from the plurality of memory blocks BLK1 to BLKz in response to an address ADDR and applies a program voltage Vpgm generated by the voltage generator 150 to a selected word line of the selected memory block.

3) Perform Verify Operation (S230)

After the program voltage apply operation (S220) is completed, a verify voltage Vverify generated by the voltage generator 150 is applied to the selected word line of the selected memory block, and then the plurality of page buffers PB1 to PBm senses the potential levels of the bit lines BL1 to BLm, respectively, to perform a program verify operation on the LSB data stored in the selected memory block.

4) Increase Program Voltage (S240)

When a result of the program verify operation (S230) on the LSB data is determined to be failed, a level of the program voltage Vpgm is increased by a step voltage and reset, and then operations starting from the applying of the program voltage (S220) which is described above are performed again.

5) Perform Fail Bit Masking Operation (S250)

When the result of the program verify operation (S230) on the LSB data is determined to be passed, the control logic 140 controls the peripheral circuits in order to perform a fail bit masking operation.

In the fail bit masking operation, the read/write circuit 130 is controlled to detect a fail bit Fail Bit using a column scanning method, and, if the fail bit Fail Bit is detected and transmitted to the control logic 140, the control logic 140 outputs the column address Column Addressing corresponding to the fail bit Fail Bit to the address decoder 120. The address decoder 120 controls the read/write circuit 130 to deactivate a page buffer corresponding to the column address Column Addressing or sets the page buffer in a program inhibition mode by masking a program operation for the page buffer based on the column address Column Addressing when a subsequent MSB data program operation is performed.

6) Read LSB Data (S260)

When the fail bit masking operation (S250) is performed, the plurality of page buffers PB1 to PBm included in the read/write circuit 130 reads and temporarily stores the LSB data. A read operation may be performed on the LSB data while the fail bit masking operation (S250) is performed, as illustrated in FIG. 4.

7) Input MSB Data (S270)

When the read operation (S260) on the LSB data is completed, MSB data of the program data is input from the outside of the semiconductor memory device and temporarily stored in the read/write circuit 130. The program data is generated and temporarily stored by combining the temporarily stored LSB data and the input MSB data. Thus, the potential levels of the bit lines BL1 to BLm are adjusted according to the generated program data.

8) Apply Program Voltage (S280)

When the program voltage apply operation is performed, the program voltage Vpgm generated by the voltage generator 150 is applied to the selected word line of the selected memory block to store the MSB data in the selected memory block.

9) Perform Verify Operation (S290)

After the program voltage apply operation (S280) is completed, the verify voltage Vverify generated by the voltage generator 150 is applied to the selected word line of the selected memory block, and then the plurality of page buffers PB1 to PBm senses the potential levels of the corresponding bit lines BL1 to BLm to perform a program verify operation on the MSB data stored in the selected memory block.

The program voltage apply operation (S280) and the program verify operation (S290) on the MSB data may be performed while the fail bit masking operation (S250) is performed, as illustrated in FIG. 4. Thus, a program operating time of the semiconductor memory device may be reduced.

In the embodiment of the present disclosure, the program voltage apply operation (S280) and the program verify operation (S290) on the MSB data are shown to be performed one time during the fail bit masking operation (S250). However, these operations may be performed a predetermined number of times that is two or more times.

10) Increase Program Voltage (S300)

When a result of the program verify operation (S290) with respect to the MSB data is determined to be failed, a level of the program voltage Vpgm is increased by a step voltage and reset.

11) Apply Program Voltage (S310)

The program voltage Vpgm, which is reset to the increased level, is applied to the selected word line.

12) Perform Verify Operation (S320)

After the program voltage apply operation (S310) is completed, the verify voltage Vverify generated by the voltage generator 150 is applied to the selected word line of the selected memory block, and then the plurality of page buffers PB1 to PBm senses the potential levels of the corresponding bit lines BL1 to BLm to perform the program verify operation on the MSB data.

On the other hand, if the result of the program verify operation (S290) with respect to the MSB data is determined to be passed, the program operation is completed. When the result is determined to be failed, the operations starting from the increase of the level of the program voltage (S300) are performed again.

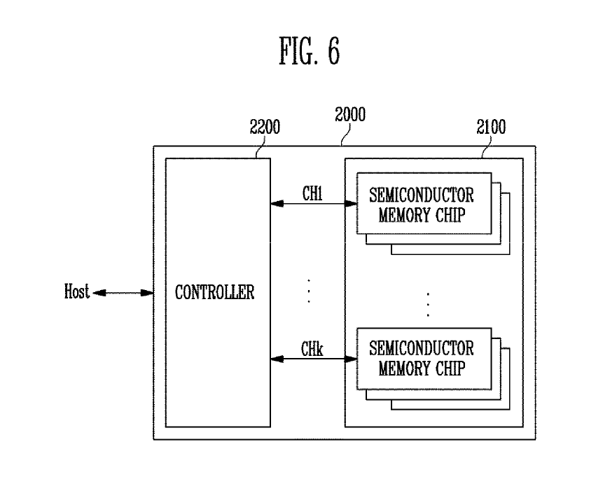

FIG. 5 is a block diagram showing a memory system including the semiconductor memory device of FIG. 1.

Referring to FIG. 5, the memory system 1000 includes the semiconductor memory device 100 and a controller 1100.

The semiconductor memory device 100 may be configured and operate in the same manner as that described with reference to FIG. 1. Thus, for the simplicity of description, the description thereof will be omitted.

The controller 1100 is connected to a host Host and the semiconductor memory device 100. The controller 1100 is configured to access the semiconductor memory device 100 in response to a request from the host Host. For example, the controller 1100 is configured to control read, write, erase, and background operations of the semiconductor memory device 100. The controller 1100 is configured to provide an interface between the semiconductor memory device 100 and the host Host. The controller 1100 is configured to drive firmware in order to control the semiconductor memory device 100.

The controller 1100 includes a random access memory (RAM) 1110, a processing unit 1120, a host interface 1130, a memory interface 1140, and an error correction block 1150. The RAM 1110 is used as at least one of an operational memory of the processing unit 1120, a cache memory between the semiconductor memory device 100 and the host Host, and a buffer memory between the semiconductor memory device 100 and the host Host. The processing unit 1120 controls overall operations of the controller 1100. Further, the controller 1100 may temporarily store program data provided from the host Host when a write operation, i.e., a program operation, is performed.

The host interface 1130 includes a protocol to exchange data between the host Host and the controller 1100. In an embodiment, the controller 1100 is configured to communicate with the host Host through at least one of various interface protocols such as a Universal Serial Bus (USB) protocol, a multimediacard (MMC) protocol, a peripheral component interconnect (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, a private protocol, etc.

The memory interface 1140 interfaces with the semiconductor memory device 100. In an embodiment, the memory interface 1140 includes a NAND interface or a NOR interface.

The error correction block 1150 is configured to detect and correct an error in data received from the semiconductor memory device 100 using an error correcting code (ECC). The processing unit 1120 adjusts a level of a read voltage according to an error detection result of the error correction block 1150 and controls the semiconductor memory device 100 to perform a read operation again based on the adjusted read voltage. In an embodiment, the error correction block 1150 may be implemented in the controller 1100.

The controller 1100 and the semiconductor memory device 100 may be integrated into a single semiconductor device. In an embodiment, the controller 1100 and the semiconductor memory device 100 may be integrated into one semiconductor device and configure a memory card. For example, the controller 1100 and the semiconductor memory device 100 are integrated into one semiconductor device and configure a memory card such as a personal computer (PC) card (e.g., personal computer memory card international association (PCMCIA) card), a compact flash (CF) card, a smartmedia (SM) card (SMC), a memory stick, an MMC (e.g., reduced size MMC (RS-MMC) or MMCmicro), a secure digital (SD) card (e.g., miniSD, microSD, or SD high capacity (SDHC)), a universal flash storage (UFS), or the like.

The controller 1100 and the semiconductor memory device 100 may be integrated into a solid state drive (SSD). The SSD includes a storage device configured to store data in a semiconductor memory device. When the memory system 1000 is used as the SSD, an operating speed of the host Host connected to the memory system 1000 is significantly enhanced.

In an embodiment, the memory system 1000 is provided as at least one of various components of an electronic device such as a computer, an ultra mobile PC (UMPC), a workstation, a netbook, a personal digital assistant (PDA), a portable computer, a web tablet, a wireless phone, a mobile phone, a smartphone, an e-book, a portable multimedia player (PMP), a portable game console, a navigation device, a black box, a digital camera, a 3-dimensional television, a digital audio recorder, a digital audio player, a digital picture recorder, a digital picture player, a digital video recorder, a digital video player, a device for wirelessly transmitting and receiving information, at least one of various electronic devices configuring a home network, at least one of various electronic devices configuring a computer network, at least one of various electronic devices configuring a telematics network, an RFID device, and at least one of various components configuring a computing system, or the like.

In an embodiment, the semiconductor memory device 100 or the memory system 1000 may be mounted using various forms of packages. For example, the semiconductor memory device 100 or the memory system 1000 may be packaged using a package on package (PoP), ball grid arrays (BGAs), chip scale packages (CSPs), a plastic leaded chip carrier (PLCC), a plastic dual inline package (PDIP), a die in waffle pack, a die in wafer form, a chip on board (COB), a ceramic dual inline package (CERDIP), a plastic metric quad flat pack (MQFP), a thin quad flatpack (TQFP), a small outline integrated circuit (SOIC), a shrink small outline package (SSOP), a thin small outline (TSOP), a thin quad flatpack (TQFP), a system in package (SIP), a multi chip package (MCP), a wafer-level fabricated package (WFP), a wafer-level processed stack package (WSP), or the like, and may be mounted.

FIG. 6 is a block diagram showing an application example of the memory system shown in FIG. 5.

Referring to FIG. 6, the memory system 2000 includes a semiconductor memory device 2100 and a controller 2200. The semiconductor memory device 2100 includes a plurality of semiconductor memory chips. The plurality of semiconductor memory chips is divided into a plurality of groups.

In FIG. 6, the plurality of groups is shown to communicate with the controller 2200 through first to k^{th} channels CH1 to CHk, respectively. Each semiconductor memory chip is configured and operates similar to the semiconductor memory device 100 described with reference to FIG. 1.

In another embodiment, the plurality of groups may be configured to communicate with the controller 2200 through one common channel. The controller 2200 is configured similar to the controller 1100 described with reference to FIG. 5 and configured to control the plurality of semiconductor memory chips of the semiconductor memory device 2100 through the plurality of channels CH1 to CHk.

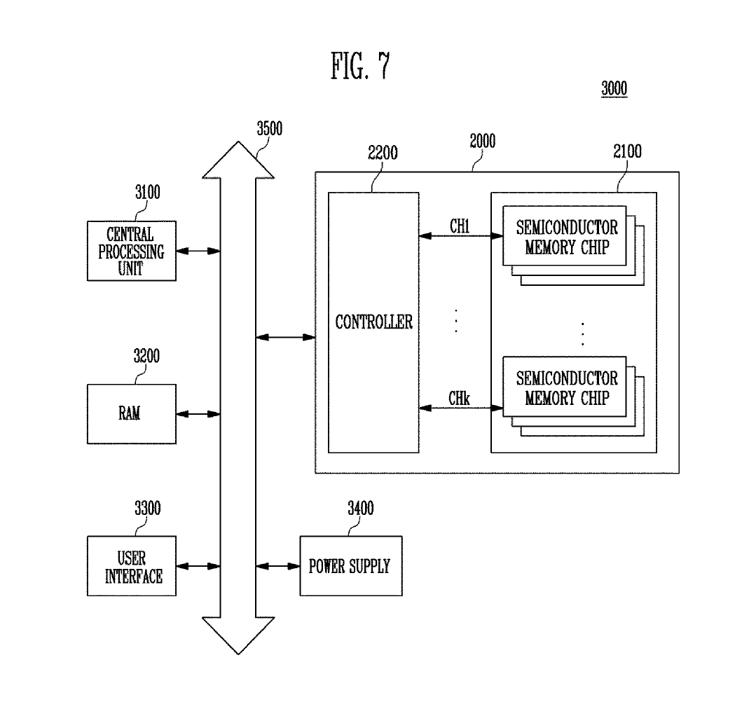

FIG. 7 is a block diagram showing a computing system including the memory system described with reference to FIG. 6.

Referring to FIG. 7, the computing system 3000 includes a central processing unit 3100, a RAM 3200, a user interface 3300, a power supply 3400, a system bus 3500, and the memory system 2000.

The memory system 2000 is electrically connected to the central processing unit 3100, the RAM 3200, the user interface 3300, and the power supply 3400 through the system bus 3500. Data, which is provided through the user interface 3300 or processed by the central processing unit 3100, is stored in the memory system 2000.

In FIG. 7, the semiconductor memory device 2100 is connected to the system bus 3500 through the controller 2200. However, the semiconductor memory device 2100 may be configured to be directly connected to the system bus 3500. In this embodiment, the controller 220 may be omitted and thus a function of the controller 2200 may be performed by the central processing unit 3100 and the RAM 3200.

In FIG. 7, the memory system 2000 described with reference to FIG. 6 is provided. However, the memory system 2000 may be replaced by the memory system 1000 described with reference to FIG. 5. In an embodiment, the computing system 3000 may include both of the memory systems 1000 and 2000 described with reference to FIGS. 5 and 6, respectively.

According to the embodiments of the present disclosure, since an LSB data read operation and some processes of an MSB data program operation are performed concurrently when a fail bit masking operation is performed after an LSB data program operation is performed, a program operating time of a semiconductor memory device can be reduced.

In the drawings and specification, there have been disclosed illustrative embodiments of the present disclosure, and although specific terms are employed, they are used in a generic and descriptive sense only and not for purposes of limitation. As for the scope of the disclosure, it is to be set forth in the following claims. Therefore, it will be understood by those of ordinary skill in the art that various changes in form and details may be made therein without departing from the spirit and scope as defined by the following claims.

1. A semiconductor memory device, comprising:
a memory cell array including a plurality of memory cells;
a peripheral circuit configured to program a memory cell selected from the memory cells when a program operation is performed; and
a control logic configured to control the peripheral circuit during the program operation,
wherein the control logic controls the peripheral circuit so that a fail bit masking operation is performed to deactivate a most significant bit (MSB) data program operation with respect to a column that is determined to be failed as a result of a least significant bit (LSB) program operation, among a plurality of columns corresponding to the plurality of memory cells, and controls the peripheral circuit so that an MSB data program operation with respect to the remaining columns except the failed column among the plurality of columns is performed while the fail bit masking operation is performed, during the program operation.

2. The device of claim 1, wherein the control logic controls the peripheral circuit so that, in the MSB data program operation with respect to the remaining columns, a program voltage apply operation and a verify operation are performed a number of times while the fail bit masking operation is performed.

3. The device of claim 1, wherein the memory cells are arranged in the plurality of columns, and wherein the peripheral circuit comprises:
a read/write circuit including a plurality of page buffers coupled to the plurality of columns of the memory cell array, respectively, and configured to perform a fail bit check operation to detect a fail bit and output the detected fail bit to the control logic when the fail bit masking operation is performed; and
an address decoder configured to deactivate a page buffer corresponding to a column address of the failed column in which the fail bit is generated when the fail bit masking operation is performed or to set the page buffer in a program inhibition mode.

4. The device of claim 3, wherein the read/write circuit detects the failed column in which the fail bit is generated using a column scanning method when the fail bit check operation is performed.

5. The device of claim 1, wherein the control logic comprises:
a masking enable signal generator configured to output a fail bit masking enable signal when the fail bit masking operation is performed;
a page buffer controller configured to receive a fail bit and output fail bit information on the received fail bit when the fail bit masking operation is performed; and
a fail bit address signal generator configured to output a column address of the failed column in which the fail bit is generated according to the fail bit masking enable signal and the fail bit information.

6. The device of claim 1, wherein the control logic controls the peripheral circuit so that the fail bit masking operation and the MSB data program operation with respect to the remaining columns are performed concurrently, and
wherein the control logic controls the peripheral circuit so that a least significant bit (LSB) data read operation is performed prior to the MSB data program operation with respect to the remaining columns.

7. The device of claim 6, wherein the LSB data read operation is performed when the fail bit masking operation is performed.

8. A method of operating a semiconductor memory device, the method comprising:
performing a least significant bit (LSB) data program operation on selected memory cells of a plurality of memory cells;
performing a fail bit masking operation to deactivate a most significant bit (MSB) data program operation with respect to a column that is determined to be failed as a result of the LSB data program operation, among a plurality of columns corresponding to the plurality of memory cells; and
performing an MSB data program operation with respect to the remaining columns except the failed column, among the plurality of columns, while the fail bit masking operation is performed.

9. (canceled)

10. The method of claim 8, wherein an LSB data read operation is performed prior to the MSB data program operation while the fail bit masking operation is performed.

11. The method of claim 8, wherein some of the MSB data program operation comprise program voltage apply operations of a predetermined number of times and verify operations of a predetermined number of times.

12. The method of claim 9, wherein performing the fail bit masking operation comprises detecting the failed column in which the fail bit is generated using a column scanning method.
